(19) United States
(12) Patent Application Publication
(10) Pub. No.: US 2011/0226324 A1
(43) Pub. Date: Sep. 22, 2011

(54) System for the Production of Single Crystal Semiconductors and Solar Panels Using the Single Crystal Semiconductors

(75) Inventor: Fritz Jürgen Wisotzki, Darmstadt (DE)

(73) Assignee: GRAIN FREE PRODUCTS, INC., Alexandria, VA (US)

(21) Appl. No.: 13/026,228

(22) Filed: Feb. 12, 2011

(30) Foreign Application Priority Data
Mar. 16, 2010 (EP) 10002736

(51) Int. Cl. H01L 31/0264; C30B 7/00; C30B 9/00; C30B 11/00; H01L 31/04; H01L 31/18

(52) U.S. Cl. 136/256; 117/11; 438/95; 257/E31.015

(57) ABSTRACT

A process and the required technical arrangement has been developed to produce single crystal solar panels or otherwise used semiconductors, which starts with the raw material to produce single crystal copper ribbons, extruded directly from the melt, with unharmed and optical surfaces onto which in the next unit a silicon or germanium film will be deposited. In the next unit the copper ribbon will be removed from the silicon film, whilst a hard plastic support or ceramic support is mounted, leaving copper contours on the silicon film to be used as electrical conductors or contacts. In the next unit a thin film is deposited of II-VI-compounds that enhance the infrared sensitivity of the base film of silicon or germanium up to 56% of the incoming light. This technology guarantees the lowest possible cost in production of the highest possible efficiency of materials for infrared applications and also for electronic applications.

### CROSS REFERENCE TO RELATED APPLICATION

This application is based on and claims the benefit of European Patent Application No. 10002736.6/EP10002796, filed Mar. 16, 2010, which is incorporated herein by reference.

### BACKGROUND OF THE INVENTION

1. Field of the Invention

The present invention relates to a process and technical arrangement for the low cost production of ready to be used solar panels and otherwise used semiconductors, consisting of single crystal ribbons of silicon or germanium, truly interfaced with deposited II-VI compound single crystal films, having copper electrical contacts or contours with a true single crystal structure, leading to an efficiency for solar applications of up to 56% of the incoming light. (II-VI compounds combine elements from groups IIB and VIA of the periodic table.)

2. Description of the Prior Art

To use single crystal structures of silicon or germanium one has to use presently silicon or germanium wafers which are cut from grown bulk single crystal materials and those wafers have to be refurbished by a very cost intensive process, but impurities implanted can never be fully removed. The same is valid for any production of solar panels or semiconductors, if machining of surfaces is involved and if the surfaces of importance for the efficiency have been exposed to air. The interface between coatings and substrates will have a higher resistivity and the lifetime of the coatings is highly limited.

### SUMMARY OF THE INVENTION

This invention leads to the utmost use of materials in their highest purity and lowest resistance with lowest corrosion factors, leading to an extreme efficiency at lowest costs, caused by the developed online process in which those materials do not need any extra handling to remove imperfections and impurities.

Accordingly, it is a principal object of the invention to provide materials that may be used in solar panels.

It is another object of the invention to provide improved semiconductors.

It is a further object of the invention to provide materials with low electrical resistance.

Still another object of the invention is to provide materials with low thermal resistance.

It is an object of the invention to provide improved elements and arrangements thereof in an apparatus for the purposes described which is inexpensive, dependable and fully effective in accomplishing its intended purposes.

These and other objects of the present invention will become readily apparent upon further review of the following specification and drawings.

### BRIEF DESCRIPTION OF THE DRAWINGS

FIG. 1 is a diagrammatic representation of unmachined extruded copper ribbon, grown directly from the melt.

FIG. 2 is a diagrammatic representation of single crystal silicon or germanium film, deposited over single crystal copper foil.

FIG. 3 is a diagrammatic representation of single crystal silicon or germanium film, over a hard plastic or ceramic support and single crystal electrical contacts or contours.

FIG. 4 is a diagrammatic representation of a single crystal film of II-IV compounds, over single crystal silicon or germanium film, over a hard plastic or ceramic support and single crystal electrical contacts or contours.

FIG. 5 is a diagrammatic representation of the online process.

Similar reference characters denote corresponding features consistently throughout the attached drawings.

### DETAILED DESCRIPTION OF THE PREFERRED EMBODIMENTS

It has been discovered in high energy laser applications, that if a single crystal surface of a material has been mechanically treated, a large difference in quality occurred, compared with a single crystal surface, which has an unharmed, as grown single crystal structure. On such unharmed single crystal surfaces of any material, free electrons exist in a very high density, which can be used as a webbing source, binding oncoming coating materials onto the surface of the substrate, as no other process will permit. This leads to the highest transfer of energy from one layer to the next, having practically no resistance to overcome. The lifetime of such stackings will be ultimate, because there are no impurities implanted during the whole process.

In the fully developed online process, provisions have been made, that the surfaces of the single crystal structures are not in contact with air or any particles of any material, because the environment for the process is of high quality stainless steel, and the materials used inside do not chemically react with silicon, germanium or copper.

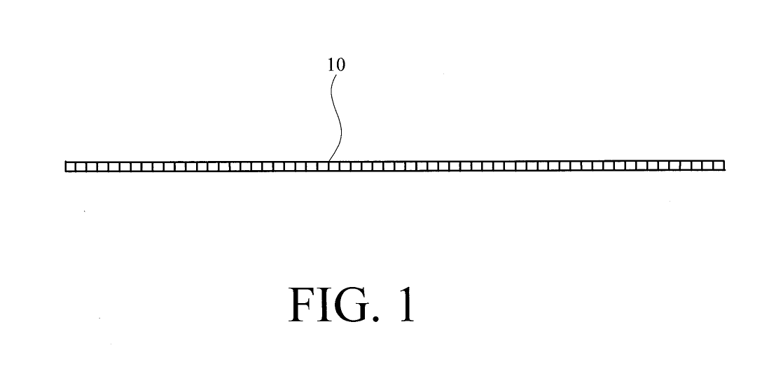

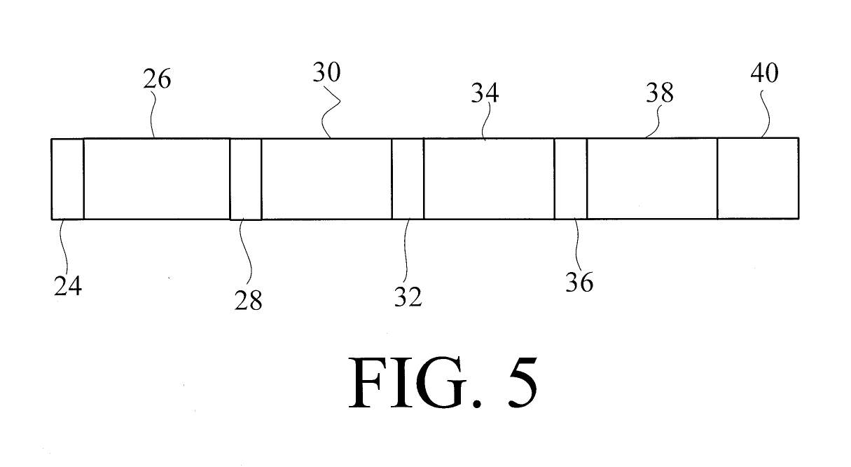

FIGS. 1 to 4 illustrate the low cost online serial production of single crystal silicon and germanium ribbons, grown as single crystal films on a copper foil, which will be chemically removed to leave contours for electrical purposes. FIG. 5 illustrates the principle of an online process to produce ready to be used solar panels and otherwise used semiconductors, that consist of true single crystal silicon or germanium ribbons, with deposited single crystal films of II-IV compounds, which have single crystal electrical contacts or contours. All single crystal structures are truly interwebbed into each other, and the interface between the structures has the lowest possible resistivity, increasing the efficiency coefficient from 49% to 56% of the incoming light, with a wave length of 10.6 microns at an angle of zero degrees. The whole online process takes place under a high purity inert gas atmosphere, and only stainless steel and high purity graphite are used in the environment, leading to the highest purity and the lowest corrosion, in particular between the interfaces of the different materials.

At the beginning of line is the material cleaning and control gate 24 shown in FIG. 5. Chambers 26, 30, 34 and 38 are separated by material insert and control gates 28, 32 and 36. The base for deposition is a copper ribbon or foil 10, shown in FIG. 1, extruded directly from the melt in the first process unit, the copper ribbon production chamber 26. The copper ribbon which has optical quality surfaces and those surfaces are free of strain, except from the force of gravity, which cannot be eliminated, but at the minor thickness of the film and the uniformity of the thickness in length, the strain is also uniform along the length of the substrate.

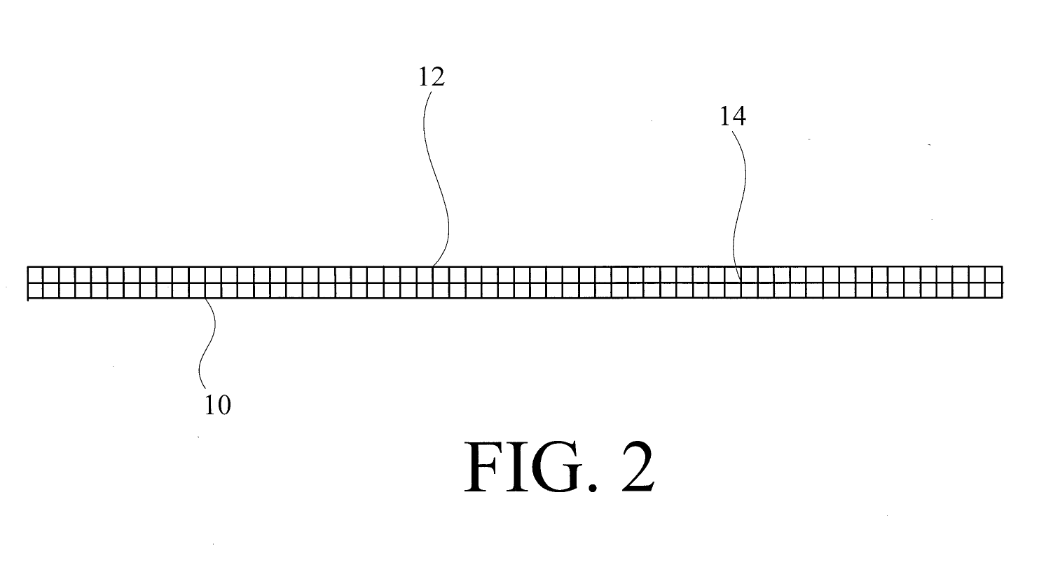

The second process unit, the silicon or germanium deposition chamber 30, holds the evaporation process of silicon or germanium in form of a falling film 12 onto the unharmed single crystal surface of the copper ribbon 10 as shown in FIG. 2. Here the force of gravity is of support, and thickness monitoring of the deposited film permits a highly uniform deposition of silicon and germanium on the single crystal copper ribbon. It has been discovered, that within a few atomic layers, a true silicon or germanium single crystal structure is growing up to the required thickness. There is low electrical and thermal resistance at the interface 14 between the two single crystal structures 10 and 12.

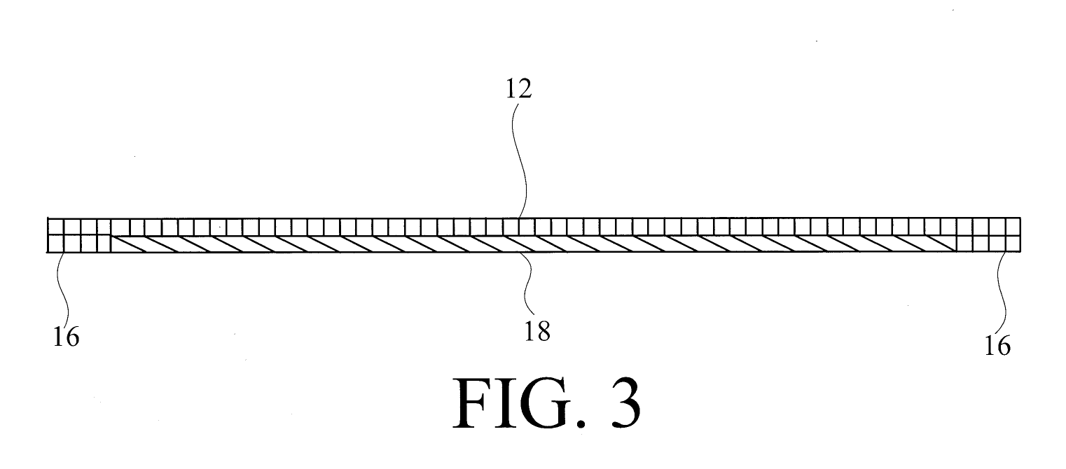

In the next online unit, the etching and support mounting chamber 34, masking of the copper contours at the bottom of the silicon or germanium films is undertaken in such a way, that the surface of the single crystal silicon or germanium film is not harmed by any means and the copper film is removed in such a way, that either contacts and/or contours 16 of single crystal copper are left at the bottom of the silicon/germanium film, as shown in FIG. 3. But most of the copper ribbon is chemically removed and replaced by a hard plastic or ceramic support 18. The contacts/contours that are left from the copper ribbon directly interface with the silicon/germanium film.

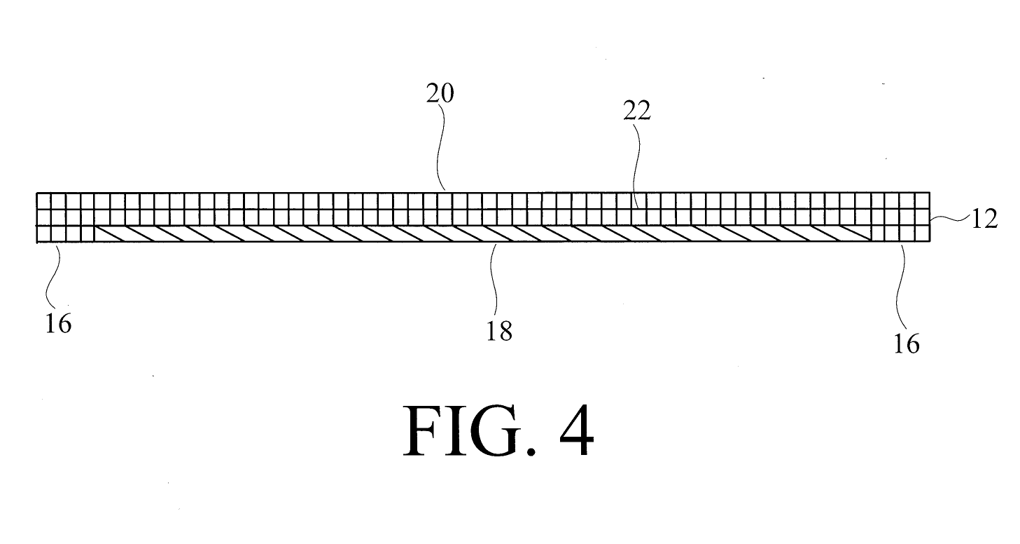

The final online stage, which takes place in the deposition of II-VI compound chamber 38, is the falling film deposition of a II-VI compound which will interweb itself in true single crystal structure into the single crystal structure of the silicon or germanium surface, as shown in FIG. 4. The highly sensitive thickness control will ensure that precision in the deposited layers of the II-VI compounds is established and there is no strain between the films, with the lowest possible electrical and thermal resistivity at the interface 22 between the single crystal layers, increasing the transfer of energy to the utmost.

The last station in the sequence is the disconnecting and framing sector, including the unloading and testing chamber 40, where the materials come to air and exit the system for further handling.

The finished product may be used to construct a solar panel consisting of a framed and protected silicon or germanium film of a defined thickness, which has a single crystal coating of a II-VI compound and copper contacts and/or contours in single crystal structure at the bottom of the silicon film, with sizes up to 200×600 millimeters.

It is to be understood that the present invention is not limited to the embodiments described above, but encompasses any and all embodiments within the scope of the following claims.

I claim:

1. An online process in which single crystal films will be deposited by a falling film technique in sequence onto substrates which have a true and unharmed single crystal surface; comprising the steps of:
laying down a copper substrate;
growing a metalloid substrate onto the copper substrate; and
growing a single crystal II-VI compound structure onto the metalloid substrate.

2. The online process according to claim 1, wherein the metalloid substrate is composed of silicon.

3. The online process according to claim 1, wherein the metalloid substrate is composed of germanium.

4. The online process according to claim 1, wherein the II-VI compound is composed of zinc and selenium.

5. The online process according to claim 1, wherein the II-VI compound is composed of zinc and sulfur.

6. The online process according to claim 1, wherein the II-VI compound is composed of cadmium and tellurium.

7. The online process according to claim 1, wherein the II-VI compound is composed of cadmium, mercury and tellurium.

8. An online process, comprising the, steps of:
laying down a copper single crystal substrate;
depositing a metalloid which grows from the copper substrate into a true single crystal structure;
chemically removing the copper substrate to leave copper contacts that are interwebbed with the crystal structure of the metalloid.

9. The online process according to claim 8, wherein the metalloid substrate is composed of silicon.

10. The online process according to claim 8, wherein the metalloid substrate is composed of germanium.

11. The online process according to claim 8, wherein the II-VI compound is composed of zinc and selenium.

12. The online process according to claim 8, wherein the II-VI compound is composed of zinc and sulfur.

13. The online process according to claim 8, wherein the II-VI compound is composed of cadmium and tellurium.

14. The online process according to claim 8, wherein the II-VI compound is composed of cadmium, mercury and tellurium.

15. A solar panel, comprising:
a framed and protected metalloid film of a defined thickness;
a single crystal coating of a II-VI compound over the metalloid film; and
copper contacts in single crystal structure at the bottom of the metalloid film.

16. The online process according to claim 15, wherein the metalloid substrate is composed of silicon.

17. The online process according to claim 15, wherein the metalloid substrate is composed of germanium.

18. The online process according to claim 15, wherein the II-VI compound is composed of zinc and selenium.

19. The online process according to claim 15, wherein the II-VI compound is composed of zinc and sulfur.

20. The online process according to claim 15, wherein the II-VI compound is composed of cadmium and tellurium.
